(19) United States
(12) Patent Application Publication
(10) Pub. No.: US 2007/0024370 A1
(43) Pub. Date: Feb. 1, 2007

(54) Power amplifier capable of adjusting compensation for distortion in amplification and communication apparatus employing the same

(75) Inventors: Michitoshi Hirata, Tenri-shi (JP); Yoshiteru Ishimaru, Tenri-shi (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/493,758

(22) Filed: Jul. 27, 2006

(30) Foreign Application Priority Data
Jul. 29, 2005 (JP) 2005-220704(P)

(51) Int. Cl. H03G 3/10

(52) U.S. Cl. 330/285

(57) ABSTRACT

A variable impedance circuit includes a capacitor and a MOSFET and is connected between the base of a bipolar transistor and a ground node. The capacitor acts to the open for a direct-current component. The MOSFET varies impedance for an alternate-current component. A base voltage ration portion includes first and second resistors, which set a bias applied to the base of the bipolar transistor. More specifically, the base voltage generation portion divides an operating voltage supplied through a voltage terminal by a ratio of the first and second resistors to generate a base voltage of the bipolar transistor.

This nonprovisional application is based on Japanese Patent Application No. 2005-220704 filed with the Japan Patent Office on Jul. 29, 2005, the entire contents of which are hereby incorporated by reference.

### BACKGROUND OF THE INVENTION

1. Field of the Invention

The present invention relates generally to power amplifiers and communication apparatuses and particularly to power amplifiers required to be reduce distortion and communication apparatuses employing the same.

2. Description of the Background Art

Mobile phones, wireless communications and the like typically employ quadrature phase shift keying (QPSK), quadrature amplitude modulation (QAM) and the like as digital modulation systems. These digital modulation systems superposes information on both the amplitude and phase of a signal. Accordingly the systems require faithfully amplifying the signal in waveform. Accordingly, power amplifiers employed in the digital modulation systems indicated above are required to operate to suppress or prevent distortion in amplification.

Japanese Patent No. 3607855 discloses a power amplifier compensating for distortion in amplification. An example of this power amplifier will be described hereinafter with reference to a drawing.

FIG. 23 is a circuit diagram showing a circuit configuration of a conventional power amplifier 1100.

With reference to FIG. 23, the conventional power amplifier 1100 includes an input terminal 101, a power amplifying, emitter grounded bipolar transistor 102, an output terminal 103, a bipolar transistor 104 for variable impedance, a voltage terminal 105, a resistor 110, and a capacitor 504.

Input terminal 101 receives a radio frequency signal RFin. Output terminal 103 outputs a radio frequency signal RFout amplified via the collector of bipolar transistor 102. Voltage terminal 105 supplies an operating voltage VB. Resistor 110 is connected between voltage terminal 105 and the base of bipolar transistor 104. Capacitor 504 is connected between voltage terminal 105 and a ground node.

Bipolar transistor 104 has an emitter connected to the base of bipolar transistor 102, a collector connected to voltage terminal 105, and a base connected to resistor 110. Bipolar transistor 104 has an emitter current equal to the sum of base and collector currents, and the collector current is substantially proportional to the base current. Accordingly, the emitter current of bipolar transistor 104 has a diode-like current-voltage characteristic for operating voltage VB. As such, bipolar transistor 104 functions as a variable impedance element.

Bipolar transistor 104 has its base current variable by resistor 110. Accordingly it also has its collector and emitter currents variable by resistor 110. As such, even after bipolar transistor 104 to be used is selected, its variable resistance characteristic can be adjusted by resistor 110. This can provide an increased degree of freedom in adjusting correction of distortion in power amplifier 1100.

Japanese Patent Laying-Open No. 2005-006212 discloses a power amplifier that adjusts an extent of compensation for distortion in amplification by a control signal. An example of this power amplifier will be described with reference to a drawing.

FIG. 24 is a circuit diagram showing a circuit configuration of a conventional power amplifier 1200.

With reference to FIG. 24, the conventional power amplifier 1200 includes an input terminal 101, a power amplifying, emitter grounded hetero-junction bipolar transistor (HTB) 102, an output terminal 103, a voltage terminal 105, a capacitor 107, a resistor 506, a variable impedance element 2201, and a control circuit 2202.

Input terminal 101 receives a radio frequency signal RFin. Output terminal 103 outputs a radio frequency signal RFout amplified via the collector of bipolar transistor 102. Voltage terminal 105 supplies an operating voltage VB. Capacitor 107 is connected between input terminal 101 and the base of bipolar transistor 102.

Resistor 506 is connected between voltage terminal 105 and the base of bipolar transistor 102. By inserting resistor 506, an increase in a current of bipolar transistor 102 that is attributed to an increase in temperature can be canceled by a voltage applied between resistors, and bipolar transistor 102 can provide a thermal, steady operation.

Variable impedance element 2201 is connected between voltage terminal 105 and input terminal 101. Variable impedance element 2201 forms a path that bypasses a portion of an alternate-current (ac) component of a base current flowing via resistor 506 toward bipolar transistor 102. This can effectively suppress an increase in a voltage drop at resistor 506 and power amplifier 1200 can operate with minimized distortion for a desired output or radio frequency signal RFout.

The bypass passes a current, which has a magnitude depending on a value in impedance of variable impedance element 2201. Reducing the value in impedance effectively more suppresses an increase in a voltage drop at resistor 506 and hence increases saturation power, and together therewith, radio frequency signal RFout is increased in current and accordingly the power amplifier operates less efficiently. In other words, the saturation power and operation efficiency of power amplifier 1200 have a trade-off relationship. As such, for the value in impedance of variable impedance element 2201, there exists an optimum value in terms of high output operation and highly efficient operation.

The value in impedance of variable impedance element 2201 can be varied by a control signal CTR output from control circuit 2202. As such, if power amplifier 1200 is reduced in saturation power due to some factor, variable impedance element 2201 of the bypass can be varied by control signal CTR to improve power amplifier 1200 in saturation power.

The above described conventional power amplifiers can adjust an extent of compensation for distortion in amplification to some extent. Conventional power amplifiers, however, have a relatively narrow range of adjustment of compensation for distortion in amplification. As such, if such a conventional power amplifier is an amplifier accommodating a plurality of different frequency bands, a power amplifier of a communication system with a wide frequency band, or the like, it cannot provide compensation for distortion in amplification differently for each frequency and is accordingly in some cases limited in application for example to fine adjustment of distortion in amplification.

### SUMMARY OF THE INVENTION

The present invention contemplates a power amplifier allowing a wide range of adjustment of compensation for distortion in amplification, and a communication apparatus employing the same.

The present invention is a power amplifier receiving a signal at an input terminal, amplifying the signal, and outputting the signal thus amplified at an output terminal, including: a radio frequency signal input/output portion including a first bipolar transistor having a base directly or indirectly connected to the input terminal, a collector connected to the output terminal, and an emitter grounded; a voltage terminal supplying the radio frequency signal input/output portion with an operating voltage; a second bipolar transistor having an emitter directly or indirectly connected to the base of the first bipolar transistor; a base voltage generation portion generating a base voltage of the second bipolar transistor; and a variable impedance circuit controlling impedance for a base of the second bipolar transistor.

Preferably the radio frequency signal input/output portion further includes; a first resistor connected between the base of the first bipolar transistor and the emitter of the second bipolar transistor; and a first capacitor connected between the input terminal and the base of the first bipolar transistor.

Preferably the base voltage generation portion includes: a second resistor connected between the voltage terminal and the base of the second bipolar transistor; and a third resistor connected between the base of the second bipolar transistor and a ground node.

Preferably the variable impedance circuit includes: a second capacitor acting to be open for a direct-current component of the variable impedance circuit; and a field effect transistor having a gate directly or indirectly connected to an impedance control terminal controlling an impedance for an alternate-current component of the variable impedance circuit by a gate voltage.

Preferably the radio frequency signal input/output portion includes more than one unit formed of the first bipolar transistor, the first resistor and the first capacitor.

Preferably the variable impedance circuit has: the field effect transistor having a drain connected to the base of the second bipolar transistor, and a source connected to the second capacitor; and the second capacitor connected between a source of the field effect transistor and a ground node.

Preferably the power amplifier further includes a voltage setting circuit connected to the gate of the field effect transistor, and the voltage setting circuit includes; a fourth resistor connected between the impedance control terminal and the gate of the field effect transistor; and a fifth resistor connected between the gate of the field effect transistor and a ground node.

Preferably the variable impedance circuit includes more than one unit formed of a sixth resistor further connected between the second capacitor and a drain of the field effect transistor and the field effect transistor.

Preferably the variable impedance circuit includes a second capacitor connected to the base of the second bipolar transistor, and more than one unit formed of a seventh resistor connected to the second capacitor and a connection portion controlling impedance, the connection portion has a first pad connected to the seventh resistor, and a die area serving as ground and at least one of more than one the first pad and the die area are connected by a bonding wire.

Preferably the variable impedance circuit includes a second capacitor connected to the base of the bipolar transistor and a connection portion connected to the second capacitor via a line, and the connection portion has a second pad connected to the second capacitor on a common chip, a third pad arranged external to the chip, and an eighth resistor connected between the third pad and a ground node, and the second and third pads are connected together by a wire.

Preferably the voltage generation portion includes: a second resistor connected between the voltage terminal and the base of the second bipolar transistor; first and second diodes connected in series between the base of the second bipolar transistor and a first node; a third capacitor connected to the first and second diodes in parallel; and a ninth resistor connected between the first node and a ground node.

Preferably the radio frequency signal input/output portion further includes an inductance circuit connected between the emitter of the first bipolar transistor and a ground node and the base voltage generation portion includes a second resistor connected between the voltage terminal and the base of the second bipolar transistor, first and second diodes connected in series between the base of the second bipolar transistor and the emitter of the first bipolar transistor, and a third capacitor connected to the first and second diodes in parallel.

The present invention in another aspect provides a power amplifier receiving an input signal at an input terminal, amplifying the signal, and outputting the signal thus amplified at an output terminal, including: a radio frequency signal input/output portion including a first bipolar transistor having a base directly or indirectly connected to the input terminal, a collector connected to the output terminal, and an emitter grounded; a voltage terminal supplying the radio frequency signal input/output portion with an operating voltage; a second bipolar transistor having an emitter directly or indirectly connected to the base of the first bipolar transistor; a base voltage generation portion including a second resistor connected between the voltage terminal and a base of the second bipolar transistor; and a variable impedance circuit setting impedance for the base of the second bipolar transistor. The radio frequency signal input/output portion further includes a first resistor connected between the base of the first bipolar transistor and an emitter of the second bipolar transistor, a first capacitor connected between the input terminal and the base of the first bipolar transistor, and a variable impedance element connected between the input terminal and the emitter of the second bipolar transistor.

The present invention in still another aspect provides a communication apparatus including a power amplifier receiving a signal at an input terminal, amplifying the signal, and outputting the signal thus amplified at an output terminal, the power amplifier including: a radio frequency signal input/output portion including a first bipolar transistor having a base directly or indirectly connected to the input terminal, a collector connected to the output terminal, and an emitter grounded; a voltage terminal supplying the radio frequency signal input/output portion with an operating voltage; a second bipolar transistor having an emitter directly or indirectly connected to the base of the first bipolar transistor; a base voltage generation portion generating a base voltage of the second bipolar transistor; and a variable impedance circuit controlling impedance for a base of the second bipolar transistor.

Preferably the communication apparatus includes: a signal processing circuit processing an input signal; a local oscillator oscillating a carrier signal; a modulator receiving the carrier signal to modulate the signal thus processed; and a transmission power amplifier amplifying the signal thus modulated, wherein the transmission power amplifier includes the above power amplifier.

Preferably the communication apparatus further includes: a power supply supplying the transmission power amplifier with power; and a control portion adjusting distortion in amplification of the transmission power amplifier depending on a state of the signal processing circuit, the local oscillator and the power supply.

The present invention thus allows a wide range of adjustment of compensation for distortion in amplification.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram showing a circuit configuration of a power amplifier 50 serving as a background for illustrating a first embodiment of the present invention.

FIG. 2 is a circuit diagram showing a circuit configuration of a power amplifier 100 in the first embodiment of the present invention.

FIG. 3 represents a relationship between power output from power amplifier 100 and amplitude distortion of power amplifier 100 as a MOSFET 112 varies in gate voltage Vg.

FIG. 4 represents a relationship between power output from power amplifier 100 and phase distortion of power amplifier 100 as MOSFET 112 varies in gate voltage Vg.

FIG. 5 represents a relationship between power output from power amplifier 100 and EVM of power amplifier 100 as MOSFET 112 varies in gate voltage Vg.

FIG. 6 is a circuit diagram showing a circuit configuration of a power amplifier 50S serving as a comparative example for the first embodiment of the present invention.

FIG. 7 represents a relationship between power output from power amplifier 50S and amplitude distortion of power amplifier 50S as a resistor 501 varies in resistance.

FIG. 8 represents a relationship between power output from power amplifier 50S and phase distortion of power amplifier 50S as resistor 501 varies in resistance.

FIG. 9 represents a relationship between power output from power amplifier 50S and amplitude distortion of power amplifier 50S as a resistor 502 varies in resistance.

FIG. 10 represents a relationship between power output from power amplifier 50S and phase distortion of power amplifier 50S as resistor 502 varies in resistance.

FIGS. 11 and 12 are circuit diagrams showing circuit configurations of power amplifiers 100A and 100B in first and second exemplary variations, respectively, of the first embodiment of the present invention.

FIGS. 13, 14 and 15 are circuit diagrams showing circuit configurations of power amplifiers 200, 300 and 400 in second, third and fourth embodiments, respectively, of the present invention.

FIG. 16 shows a specific configuration of a variable impedance circuit 30X in power amplifier 400.

FIG. 17 is a circuit diagram showing a circuit configuration of a power amplifier 500 in a fifth embodiment of the present invention.

FIG. 18 shows a specific configuration of a variable impedance circuit 30Y in power amplifier 500.

FIGS. 19 and 20 are circuit diagrams showing circuit configurations of power amplifiers 600 and 700 in sixth and seventh embodiments, respectively, of the present invention.

FIG. 21 represents a relationship between time and voltage at each portion of power amplifier 700.

FIG. 22 is a block diagram schematically showing a configuration of a communications apparatus 800 in an eighth embodiment of the present invention.

FIGS. 23 and 24 are circuit diagrams showing circuit configurations of conventional power amplifiers 1100 and 1200, respectively.

### DESCRIPTION OF THE PREFERRED EMBODIMENTS

Hereinafter the embodiments of the present invention will more specifically be described with reference to the drawings. Note that in the figures, identical or like components are identically denoted and will not be described repeatedly.

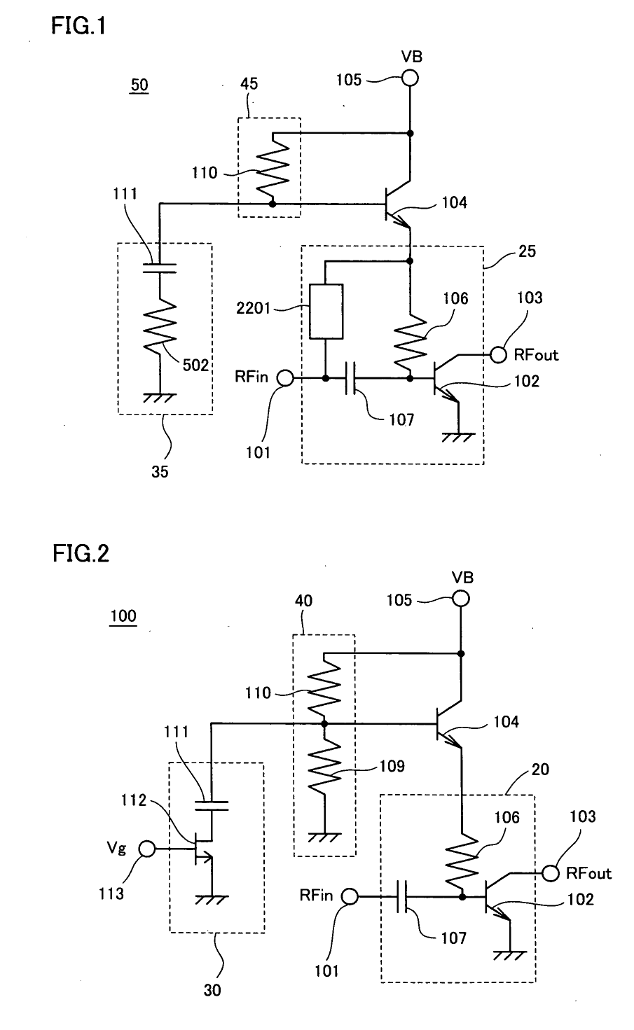

FIG. 1 is a circuit diagram showing a circuit configuration of a power amplifier 50 serving as a background for illustrating a first embodiment of the present invention.

With reference to FIG. 1, power amplifier 50 includes a radio frequency signal input/output portion 25, an impedance circuit 35, a base voltage generation portion 45 including a resistor 110, a bipolar transistor 104, and a voltage terminal 105. Radio frequency signal input/output portion 25 includes an input terminal 101, a power amplifying, emitter grounded bipolar transistor 102, an output terminal 103, a resistor 106, a capacitor 107, and a variable impedance element 2201. Impedance circuit 35 includes a capacitor 111 and a resistor 502.

Input terminal 101 receives a radio frequency signal RFin. Output terminal 103 outputs a radio frequency signal RFout amplified via the collector of bipolar transistor 102. Resistor 106 is connected between the emitter of bipolar transistor 104 and the base of bipolar transistor 102. Resistor 106 adjusts a base current flowing to bipolar transistor 102. Resistor 106 may be absent.

Capacitor 107 is connected between input terminal 101 and the base of bipolar transistor 102. Variable impedance element 2201 is connected between input terminal 101 and the emitter of bipolar transistor 104.

Bipolar transistor 104 has an emitter connected to the base of bipolar transistor 102, a collector connected to voltage terminal 105, and a base connected to resistor 110. Voltage terminal 105 supplies an operating voltage VB. Resistor 110 is connected between voltage terminal 105 and the base of bipolar transistor 104. Capacitor 111 is connected between the base of bipolar transistor 104 and resistor 502. Resistor 502 is connected between capacitor 11 and a ground node.

Radio frequency signal RFin is input through input terminal 101 via capacitor 107 to bipolar transistor 102 at the base. Radio frequency signal RFout amplified is output at output terminal 103 via the collector of bipolar transistor 102. Bipolar transistor 102 is supplied with a base bias voltage from voltage terminal 105 via the collector and emitter of bipolar transistor 104 and through resistor 106.

It should be noted that resistor 106 is a resistor for adjusting a base voltage of bipolar transistor 102. Furthermore, capacitor 107 is a capacitor for separating, with respect to input terminal 101, bias voltage supplied to the base of bipolar transistor 102.

When radio frequency signal RFin increases in power, bipolar transistor 102 increases in base current and at resistor 106 or the like a voltage drop is caused. This decreases bipolar transistor 102 in base voltage and causes distortion in amplification, such as reduced gain.

Power amplifier 50 shown in FIG. 1 compensates for the voltage drop by bipolar transistor 104 to resolve distortion in amplification. This is done by utilizing the fact that in accordance with the amplitude of radio frequency signal RFin input, bipolar transistor 104 decreases in impedance between the collector and the emitter, and as a result bipolar transistor 102 increases in base voltage.

More specifically, a portion of radio frequency signal RFin passes through resistor 106 and is input to bipolar transistor 104 at the emitter. As a result a radio frequency voltage is generated in bipolar transistor 104 between the emitter and the base and thereby a large instantaneous voltage is generated between the emitter and the base. This manifests as an increase in direct current (dc) current in bipolar transistor 104 between the collector and the emitter. This increase in the dc current between the collector and the emitter acts to increase bipolar transistor 102 in base voltage against the drop in base voltage of bipolar transistor 102 aforementioned.

Furthermore, variable impedance element 2201 can increase and decrease a ratio to radio frequency signal RFin of radio frequency signal input to bipolar transistor 104 at the emitter. This allows a degree of compensation for distortion in amplification in power amplifier 50 to be electrically adjusted.

More specifically, variable impedance element 2201 serves as a bypass allowing radio frequency signal RFin to bypass resistor 106 and be input to bipolar transistor 104 at the emitter. Variable impedance element 2201 can be varied in value to increase/decrease a ratio to radio frequency signal RFin of a radio frequency signal input to bipolar transistor 104 at the emitter.

Power amplifier 50 can thus modify an effect increasing bipolar transistor 102 in base voltage to modify a balance with the aforementioned base voltage drop to electrically adjust a degree of compensation for distortion in amplification. Hereinafter will be described a power amplifier further improved from the above described power amplifier in accordance with an embodiment of the present invention and a communication apparatus employing the same.

### First Embodiment

FIG. 2 is a circuit diagram showing a circuit configuration of a power amplifier 100 in a first embodiment of the present invention.

Power amplifier 100 of the first embodiment shown in FIG. 2 differs from power amplifier 50 shown in FIG. 1 in that radio frequency signal input/output portion 25, impedance circuit 35 and base voltage generation portion 45 are replaced with a radio frequency signal input/output portion 20, a variable impedance circuit 30 and a base voltage generation portion 40, respectively. The portion that overlaps power amplifier 50 will not be described repeatedly.

Radio frequency signal input/output portion 25 differs from radio frequency signal input/output portion 25 in that variable impedance element 2201 is removed. Variable impedance circuit 230 differs from impedance circuit 35 in that resistor 502 is replaced with a metal oxide semiconductor (MOS) field effect transistor (hereinafter referred to as MOSFET) having an impedance control terminal 113. Base voltage generation portion 40 differs from base voltage generation portion 45 in that a resistor 109 is further introduced.

MOSFET 112 has a drain connected to a capacitor 111, a source to a ground node, and a gate to impedance control terminal 113. Resistor 109 is connected between the base of bipolar transistor 104 and a ground node.

Resistors 109, 110 set a bias applied to bipolar transistor 104 at the base. More specifically, base voltage generation portion 40 divides operating voltage VB supplied through voltage terminal 105 by a ratio of resistors 109 and 110 to generate a base voltage of bipolar transistor 104.

In the first embodiment bipolar transistor 102, 104 is implemented by silicon germanium (SiGe) bipolar transistor. Accordingly, bipolar transistors 102, 104 between their respective bases and emitters have a voltage of approximately 0.8V applied thereto. Furthermore, bipolar transistor 104 at the base has a voltage of approximately 1.6V applied thereto.

Variable impedance circuit 30 includes a capacitor 111 and a MOSFET 112 and is connected between the base of bipolar transistor 104 and a ground node. Capacitor 111 acts to be open to a dc component. MOSFET 112 varies impedance for an ac component.

In the first embodiment MOSFET 112 is implemented by an n channel MOSFET having a gate with a width of 20 μm. In the first embodiment MOSFET 112 has such a characteristic that its impedance between the source and the drain varies between approximately 5000 Ω and approximately 100 Ω by setting a gate voltage Vg via impedance control terminal 113 between 0V and 3V.

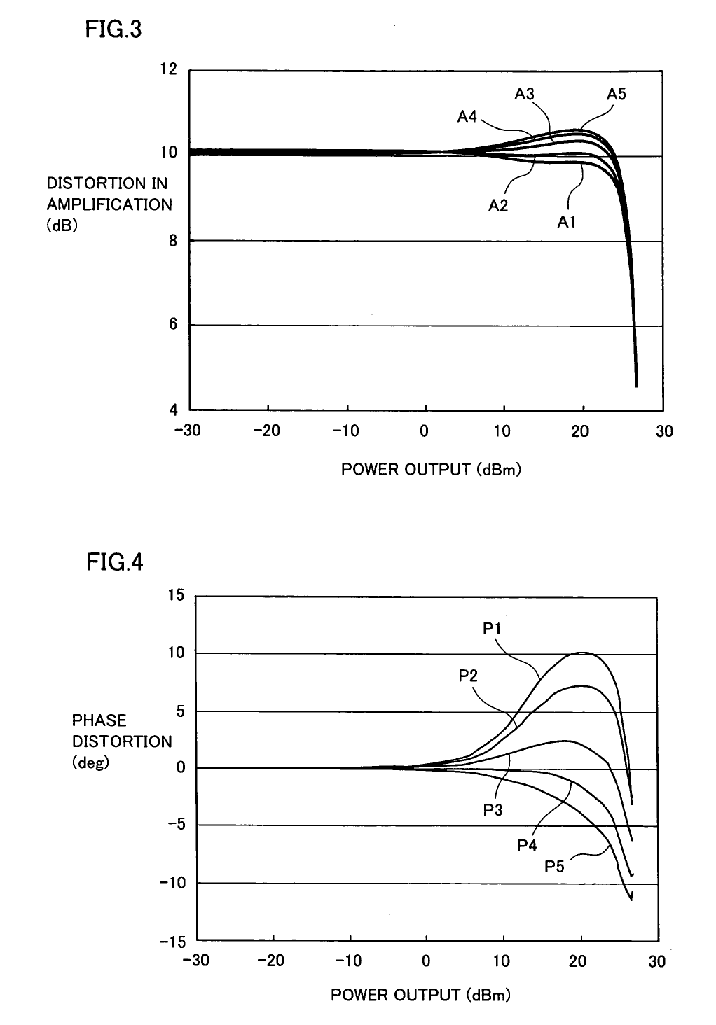

FIG. 3 represents a relationship between power output from power amplifier 100 and amplitude distortion of power amplifier 100 as MOSFET 112 varies in gate voltage Vg.

In FIG. 3 the horizontal axis represents power output of radio frequency signal RFout output at output terminal 103, as represented in dBm, and the vertical axis represents amplitude distortion of power amplifier 100, as represented in dB. With reference to FIG. 3, curves A1-A5 represent relationships between power output and amplitude distortion for gate voltages Vg of 0.5V, 1.0V, 1.5V, 2.0V and 2.5V, respectively.

As shown in FIG. 3, power amplifier 100 of the first embodiment can adjust compensation for amplitude distortion over a wide range by varying gate voltage Vg for power output between 10 dBm and 25 dBm in particular,.

FIG. 4 represents a relationship between power output from power amplifier 100 and phase distortion of power amplifier 100 as MOSFET 112 varies in gate voltage Vg.

In FIG. 4 the horizontal axis represents power output of radio frequency signal RFout output from output terminal 103, as represented in dBm, and the vertical axis represents phase distortion of power amplifier 100, as represented in degrees. Phase distortion, as referred to herein, represents in angular degrees a difference between a difference in phase between a sufficiently small signal input and the same signal output in linear operation and a difference in phase between signals input and output when each signal is output. With reference to FIG. 4, curves P1-P5 represent relationships between power output and phase distortion for gate voltages Vg of 0.5V, 1.0V, 1.5V, 2.0V and 2.5V, respectively.

As shown in FIG. 4, power amplifier 100 of the first embodiment can adjust compensation for phase distortion over a wide range by varying gate voltage Vg for power output between 5 dBm and 25 dBm in particular,.

FIG. 5 represents a relationship between power output from power amplifier 100 and error vector magnitude (EVM) thereof as MOSFET 112 varies in gate voltage Vg.

In FIG. 5 the horizontal axis represents power output of radio frequency signal RFout output from output terminal 103, as represented in dBm, and the vertical axis represents EVM (%) of power amplifier 100. EVM as referred to herein is a value measured by using a signal transmitted in the standard of 801.11a in the wireless local area network (WLAN) communications system. With reference to FIG. 5, curves E1-E5 represent relationships between power output and EVM for gate voltages Vg of 0.5V, 1.0V, 1.5V, 2.0V and 2.5V, respectively.

As shown in FIG. 5, power amplifier 100 of the first embodiment can adjust compensation for EVM over a wide range by varying gate voltage Vg for power output between 0 dBm and 15 dBm in particular,.

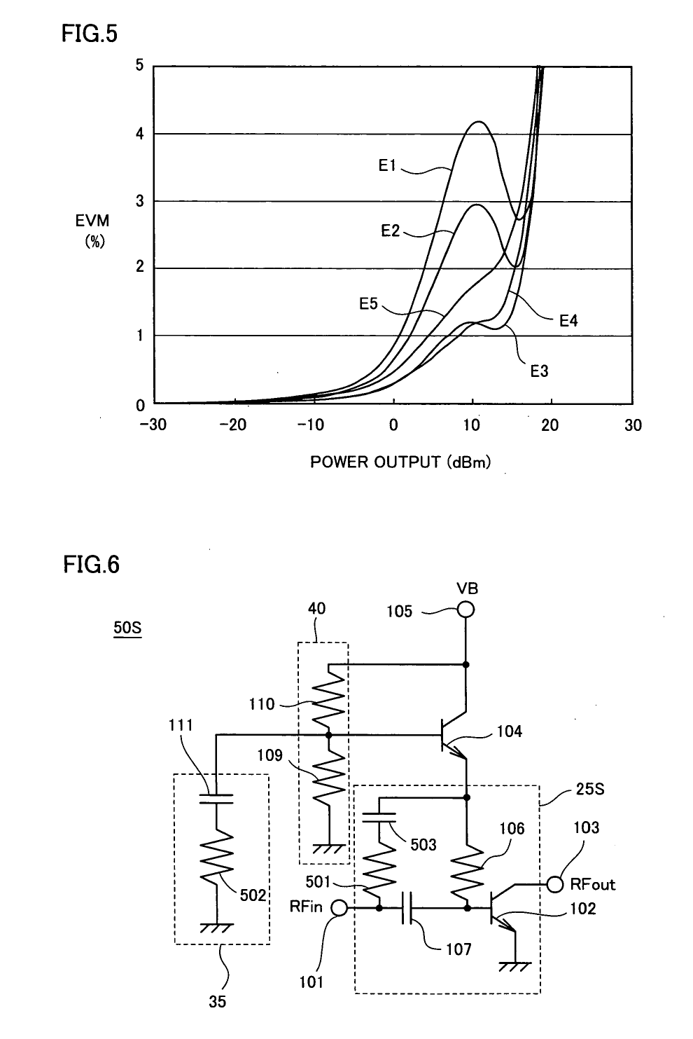

FIG. 6 is a circuit diagram showing a circuit configuration of a power amplifier 50S serving as a comparative example for the first embodiment of the present invention.

FIG. 6 shows power amplifier 50S as a comparative Example, which differs from power amplifier 50 shown in FIG. 1 as a background in that radio frequency signal input/output portion 25 is replaced with a radio frequency signal input/output portion 25S and base voltage generation portion 45 is replaced with a base voltage generation portion 40. The portion that overlaps power amplifier 50 will not be described repeatedly.

Radio frequency signal input/output portion 25S differs from radio frequency signal input/output portion 25 in that variable impedance element 2201 is replaced with a resistor 501 and a capacitor 503. Resistor 109 is connected between the base of bipolar transistor 104 and a ground node, similarly as described for power amplifier 100 shown in FIG. 2.

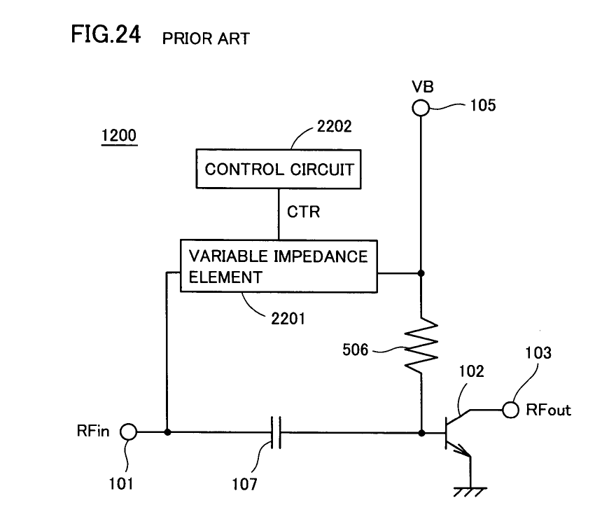

Hereinafter will be indicated a result of simulating amplitude distortion and phase distortion in power amplifier 50S of FIG. 6 when resistors 501 and 502 have their values in resistance varied as variable impedance. The range over which power amplifier 100 of the first embodiment shown in FIG. 1 can adjust compensation for distortion in amplification and phase distortion is thus compared with that over which the conventional power amplifier 1200 shown in FIG. 24 can adjust compensation for distortion in amplification and phase distortion.

In the above simulation resistors 501 and 502 have their values in resistance varied in a range of 5000 Ω to 125 Ω to correspond to variation in resistance in MOSFET 112 of FIG. 2 between the source and the drain when gate voltage Vg of MOSFET 112 is 0V to 3V.

More specifically, resistors 501 and 502 have their values in resistance varied in a range of 125 Ω (8 mS), 250 Ω (4 mS), 5000 Ω (0.2 mS) to provide conductance substantially at constant intervals. Furthermore, when one of resistors 501 and 502 is varied, the other has its value in resistance fixed at 250 Ω for the sake of illustration.

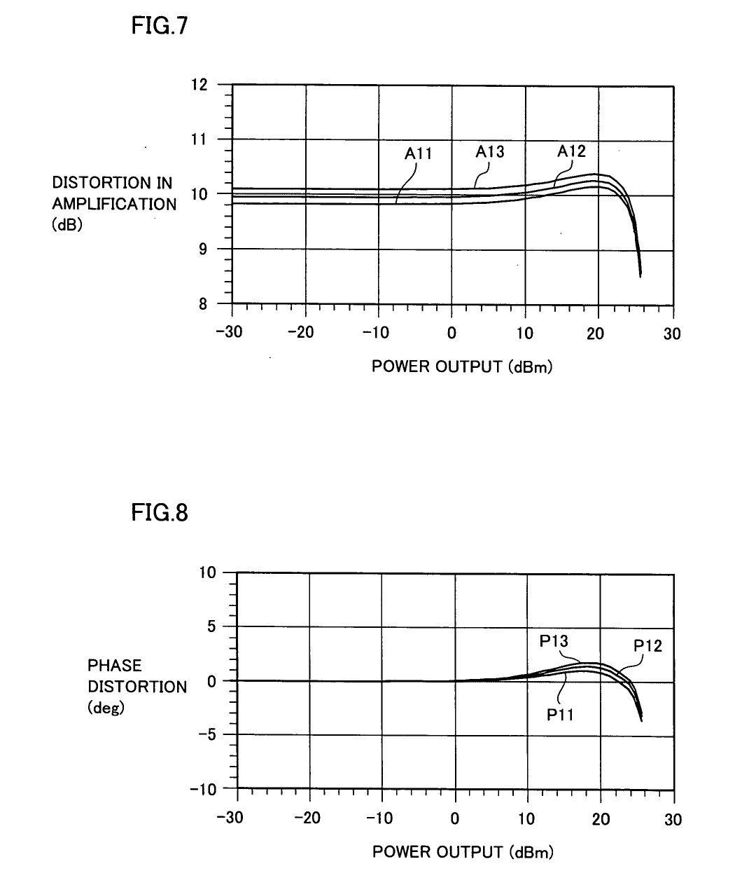

Initially the FIG. 6 power amplifier 50S has resistor 501 varied and amplitude distortion and phase distortion are thus simulated. A result thereof is shown in FIGS. 7 and 8.

FIG. 7 represents a relationship between power output from power amplifier 50S and amplitude distortion of power amplifier 50S as a resistor 501 varies in resistance.

In FIG. 7 the horizontal axis represents power output of radio frequency signal RFout output at output terminal 103, as represented in dBm, and the vertical axis represents amplitude distortion of power amplifier 50S, as represented in dB. With reference to FIG. 7, curves A1-A13 represent relationships between power output and amplitude distortion when resistor 501 is 125 Ω (8 mS), 250 Ω (4 mS) and 5000 Ω (0.2 mS), respectively.

FIG. 8 represents a relationship between power output from power amplifier 50S and phase distortion of power amplifier 50S as a resistor 501 varies in resistance.

In FIG. 8 the horizontal axis represents power output of radio frequency signal RFout output at output terminal 103, as represented in dBm, and the vertical axis represents phase distortion of power amplifier 50S, as represented in degrees. With reference to FIG. 8, curves P11-P13 represent relationships between power output and phase distortion when resistor 501 is 125 Ω (8 mS), 250 Ω (4 mS) and 5000 Ω (0.2 mS), respectively.

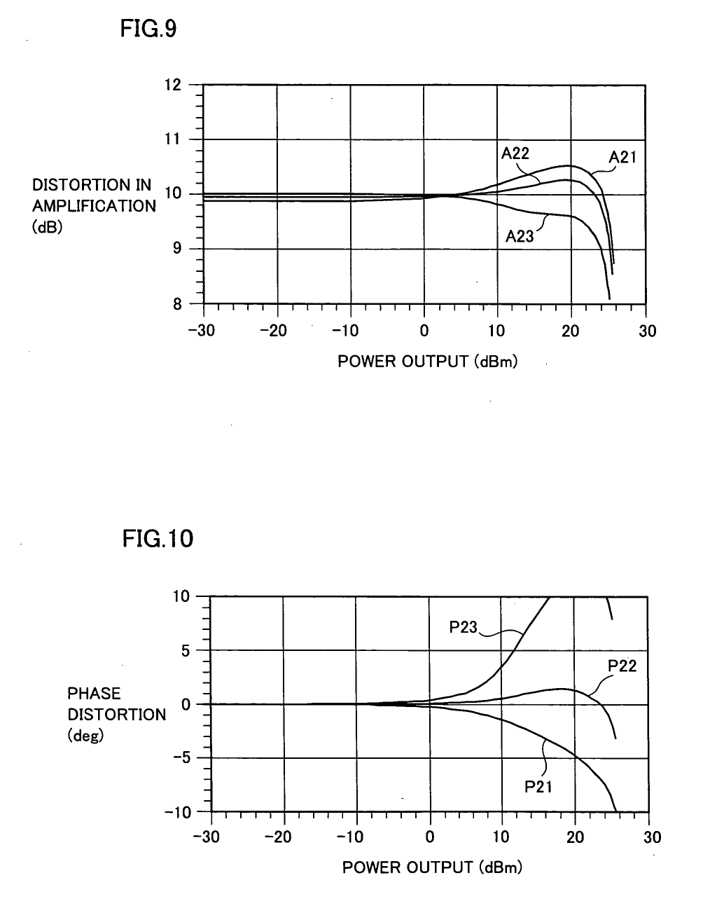

Then the FIG. 6 power amplifier 50S has resistor 502 varied and amplitude distortion and phase distortion are thus simulated. A result thereof is shown in FIGS. 9 and 10.

FIG. 9 represents a relationship between power output from power amplifier 50S and amplitude distortion of power amplifier 50S as a resistor 502 varies in resistance.

In FIG. 9 the horizontal axis represents power output of radio frequency signal RFout output at output terminal 103, as represented in dBm, and the vertical axis represents amplitude distortion of power amplifier 50S, as represented in dB. With reference to FIG. 9, curves A21-A23 represent relationships between power output and amplitude distortion when resistor 502 is 125 Ω (8 mS), 250 Ω (4 mS) and 5000 Ω (0.2 mS), respectively.

FIG. 10 represents a relationship between power output from power amplifier 50S and phase distortion of power amplifier 50S as a resistor 502 varies in resistance.

In FIG. 10 the horizontal axis represents power output of radio frequency signal RFout output at output terminal 103, as represented in dBm, and the vertical axis represents phase distortion of power amplifier 50S, as represented in degrees. With reference to FIG. 10, curves P21-P23 represent relationships between power output and phase distortion when resistor 502 is 125 Ω (8 mS), 2500 Ω (4 mS) and 5000 Ω (0.2 mS), respectively.

When FIGS. 7 and 8 and FIGS. 9 and 10 are compared, it can be seen that power amplifier 50S of FIG. 6 can adjust compensation for amplitude distortion and phase distortion over a wider range when resistor 502 has its value in resistance varied by a range than when resistor 501 does by the same range.

Thus it has been proved that power amplifier 100 of the first embodiment shown in FIG. 2 that employs MOSFET 112 at the position of resistor 502 as a variable impedance element can compensate for amplitude distortion and phase distortion over a wider range than the conventional power amplifier 1200 shown in FIG. 24 that employs variable impedance element 2201 at the position of resistor 501 and capacitor 503.

Furthermore, when FIGS. 7 and 9 are compared, in FIG. 9, i.e., when resistor 502 is varied, an amplification gain difference of 0.13 dB is provided, whereas in FIG. 7 i.e., when resistor 501 is varied, a larger amplitude gain difference of 0.27 dB is provided. Thus power amplifier 100 of the first embodiment provides a smaller variation in gain in compensating for distortion in amplification or the like than a conventional power amplifier. It can thus adjust compensation for distortion in amplification or the like even in operation.

Furthermore distortion in amplification or the like of a power amplifier also varies for difference in operating frequency. Power amplifier 100 of the first embodiment can also adjust distortion in amplification or the like for a plurality of spaced frequencies. This allows the power amplifier to be applied to compensating for distortion in amplification when the distortion in amplification varies for each frequency. For example, it could be applied to a power amplifier accommodating a plurality of different frequency ranges, a power amplifier of a communications system with a wide frequency band, and the like.

Thus power amplifier 100 of the first embodiment shown in FIG. 2 can adjust compensation for distortion in amplification and phase distortion over a wide range. As such, it can also be applied to compensating for distortion when a significantly varied state in operation provides a significantly varied characteristic in distortion. Such case would include such a case as varying a bias applied to a bipolar transistor at the base or the collector to operate it between a power saving mode and a high output mode.

Note that while in the first embodiment bipolar transistor 102, 104 is implemented by a silicon germanium (SiGe) bipolar transistor, the present invention's bipolar transistor is not limited to SiGe and may be formed of other materials such as silicon (Si), gallium arsenide (GaAs) or the like.

### First Embodiment in First Exemplary Variation

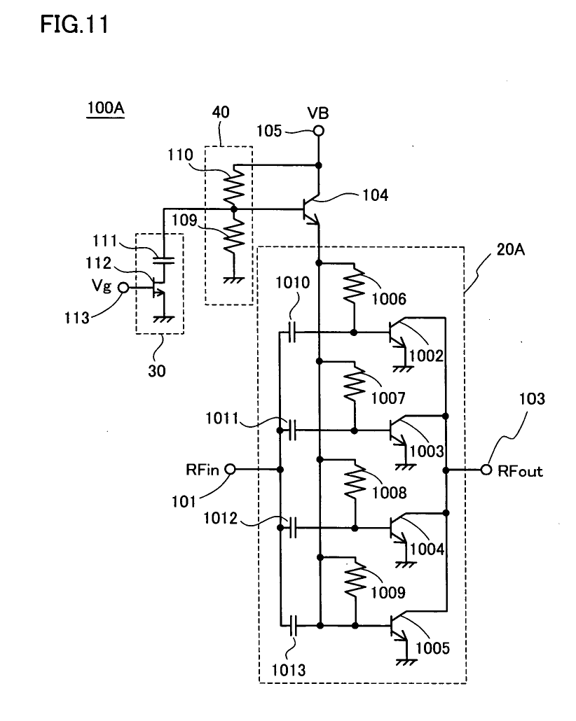

FIG. 11 is a circuit diagram showing a circuit configuration of a power amplifier 100A in a first exemplary variation of the first embodiment of the present invention.

Power amplifier 100A of the first exemplary variation shown in FIG. 11 differs from power amplifier 100 shown in FIG. 2 in that radio frequency signal input/output portion 20 is replaced with a radio frequency signal input/output portion 20A. The portion that overlaps power amplifier 100 will not be described repeatedly.

Radio frequency signal input/output portion 20A differs from radio frequency signal input/output portion 20 in that power amplifying, emitter grounded bipolar transistor 102, resistor 106 and capacitor 107 are replaced with bipolar transistors 1002-1005, resistors 1006-1009, and capacitors 1010-1013, respectively.

More specifically in the first exemplary variation radio frequency signal input/output portion 20A has a multi-unit configuration sharing input terminal 101 and output terminal 103. While FIG. 11 shows radio frequency signal input/output portion 20A having a multi-unit configuration formed of four units, the number of units is not limited thereto.

Resistors 1006-1009 are connected between the emitter of bipolar transistor 104 and the bases of bipolar transistors 1002-1005, respectively. Capacitors 1010-1013 are connected between input terminal 101 and the bases of bipolar transistors 1002-1005, respectively. Resistors 1006-1009 (ballast resistor) are configured to prevent power concentration at radio frequency signal input/output portion 20A.

As has been described above, the base voltage of bipolar transistor 104 is set by resistor 109 and 110 to be a substantially constant voltage. Alternatively, other voltage setting means may be used to set the base voltage of bipolar transistor 104. For example, resistor 109 can be eliminated or replaced with a diode.

If a voltage setting means replacing resistor 109 with a diode is employed, bipolar transistor 104 increases in base voltage for lower temperature because of a characteristic in temperature of the diode. As such, this voltage setting means has a function of temperature compensation that alleviates the dependency of power amplifier 100A in gain on temperature.

Furthermore, variable impedance circuit 30 employs MOSFET 112 as an element that varies impedance. Alternatively, a different variable impedance element may be used to vary impedance. For example, MOSFET 112 can be replaced with a variable resistive element or a variable capacitive element.

### First Embodiment in Second Exemplary Variation

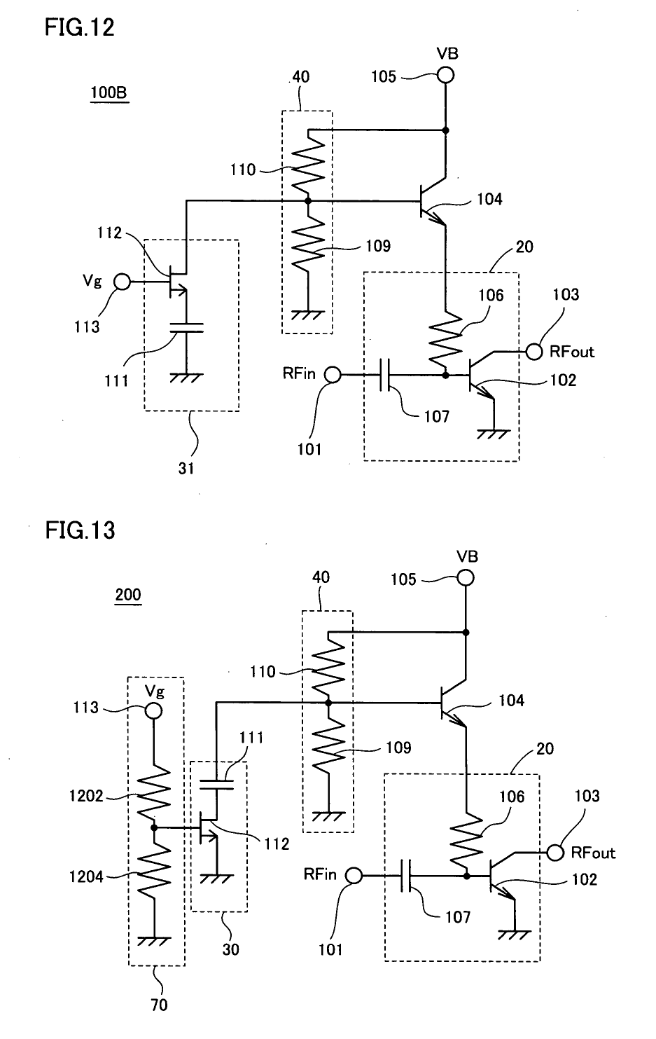

FIG. 12 is a circuit diagram showing a circuit configuration of a power amplifier 100B in a second exemplary variation of the first embodiment of the present invention.

Power amplifier 100B of the second exemplary variation shown in FIG. 12 differs from the FIG. 2 power amplifier 100 in that variable impedance circuit 30 is replaced with a variable impedance circuit 31. The portion that overlaps power amplifier 100 will not be described repeatedly.

Variable impedance circuit 31 differs from variable impedance circuit 30 in that capacitor 111 and MOSFET 112 are switched with each other. MOSFET 112 has a drain connected to the base of bipolar transistor 104, a source to capacitor 111, and a gate to impedance control terminal 113. Capacitor 111 is connected between the source of MOSFET 112 and a ground node.

Employing variable impedance circuit 31 suppresses a leak current flowing through MOSFET 112 between the source and the gate and between the drain and the source. This is preferable as controlling variable impedance circuit 31 will not affect a bias applied to bipolar transistor 102 at the base.

Variable impedance circuit 31 of FIG. 12 includes MOSFET 112 implemented by an n channel MOSFET. Alternatively, a p channel MOSFET may be used. Employing a p channel MOSFET is more preferable as the source voltage becomes to vary and controlling the gate voltage via impedance control terminal 113 is facilitated.

### Second Embodiment

FIG. 13 is a circuit diagram showing a circuit configuration of a power amplifier 200 in a second embodiment of the present invention.

Power amplifier 200 of the second embodiment shown in FIG. 13 differs from power amplifier 100 of the first embodiment in that a voltage setting circuit 70 including impedance control terminal 113 is additionally connected to MOSFET 112 at the gate. The portion that overlaps the first embodiment will not be described repeatedly.

Voltage setting circuit 70 includes resistors 1202 and 1204 and impedance control terminal 113. Resistor 1202 is connected between impedance control terminal 113 and the gate of MOSFET 112. Resistor 1204 is connected between the gate of MOSFET 112 and a ground node.

Voltage setting circuit 70 divides gate voltage Vg supplied through impedance control terminal 113 by a ratio of resistors 1202 and 1204. Voltage setting circuit 70 can have resistors 1202 and 1204 varied in ratio to vary a voltage supplied to MOSFET 112 at the gate. This can vary impedance between the source and drain of MOSFET 112 and hence adjust compensation for distortion of power amplifier 200.

Thus in accordance with the second embodiment for example if there is variation between production lots of integrated circuits including power amplifier 200, resistors 1202 and 1204 serving as a peripheral resistor of an integrated circuit of interest can be adjusted for each production lot. This can facilitate adjusting compensation for distortion of power amplifier 200. A power amplifier with reduced distortion can steadily be produced.

### Third Embodiment

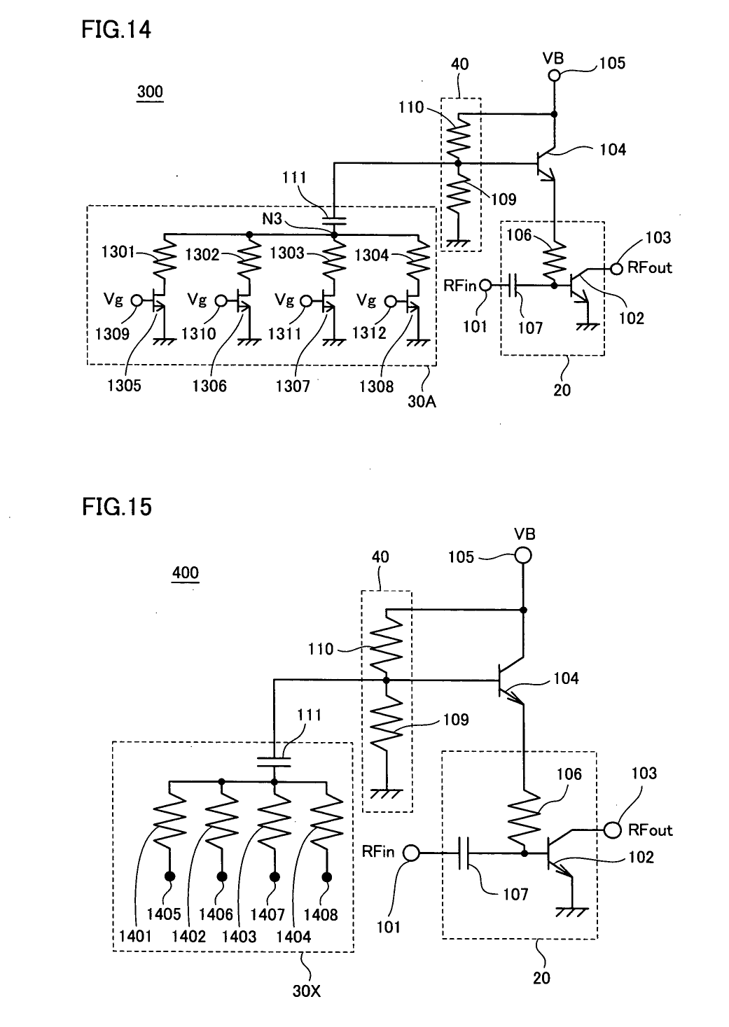

FIG. 14 is a circuit diagram showing a circuit configuration of a power amplifier 300 in a third embodiment of the present invention.

Power amplifier 300 of the third embodiment shown in FIG. 14 differs from power amplifier 100 of the first embodiment in that variable impedance circuit 30 is replaced with a variable impedance circuit 30A. The portion that overlaps the first embodiment will not be described repeatedly.

Variable impedance circuit 30A differs from variable impedance circuit 30 in that resistor 1301-1304 are connected to capacitor 111 in parallel and MOSFET 112 is replaced with MOSFETs 1305-1308.

More specifically, variable impedance circuit 30A in the third embodiment has a multi-unit configuration sharing capacitor 111. While FIG. 14 shows variable impedance circuit 30A having a multi-unit configuration formed of four units, the number of units is not limited thereto.

Resistors 1301-1304 are connected between capacitor 111 and the drains of MOSFETs 1305-1308, respectively. MOSFETs 1305-1308 have their respective drains connected to resistors 1301-1304, respectively, their respective sources each connected to a ground node, and their respective gates connected to impedance control terminals 1309-1312, respectively.

Power amplifier 300 of the third embodiment can set a value in resistance between a node N3 and a ground node by a combined resistance of resistors 1301-1304 and MOSFETs 1305-1308 controlled in resistance by impedance control terminals 1309-1312. This allows power amplifier 300 to digitally control variable impedance circuit 30A.

For example, power amplifier 300 can switch combined resistances that are preset to correspond to a plurality of operating conditions through impedance control terminals 1309-1312 to achieve a power amplification effect with reduced distortion that is optimal for the operating condition of interest.

In particular, setting resistors 1301-1304 to be 1:2:4:8 in ratio of conductance allows a combined resistance to be switched in value in resistance in 16 levels by switching MOSFETs 1305-1308 through impedance control terminals 1309-1312. This can liberate power amplifier 300 of the third embodiment from setting a voltage from a digital control circuit by employing a digital-analog conversion circuit; variable impedance circuit 30A can be controlled in impedance directly digitally to compensate for distortion.

### Fourth Embodiment

FIG. 15 is a circuit diagram showing a circuit configuration of a power amplifier 400 in a fourth embodiment of the present invention.

Power amplifier 400 of the fourth embodiment shown in FIG. 15 differs from power amplifier 100 of the first embodiment in that variable impedance circuit 30 is replaced with a variable impedance circuit 30X. The portion that overlaps the first embodiment will not be described repeatedly.

Variable impedance circuit 30X differs from variable impedance circuit 30 in that resistor 1401-1404 are connected to capacitor 111 in parallel and MOSFET 112 is replaced with connection portions 1405-1408. Variable impedance circuit 30X is configured as will be more specifically described hereinafter.

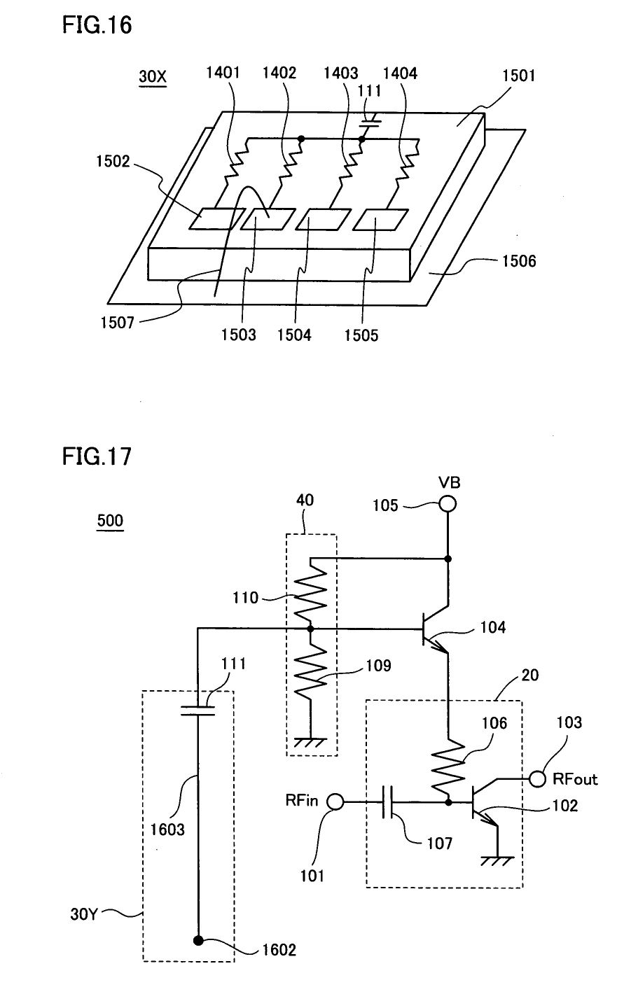

FIG. 16 specifically shows a configuration of variable impedance circuit 30X in power amplifier 400.

With reference to FIG. 16, variable impedance circuit 30X includes capacitor 111, resistors 1401-1404, a chip 1501, pads 1502-1505, a die area 1506, and a bonding wire 1507. Chip 1501 has mounted thereon each component of power amplifier 400 including variable impedance circuit 30X.

Resistors 1401-1404 are connected on chip 1501 between capacitor 111 and pads 1502-1505, respectively. In FIG. 16 pad 1503 and die area 1506 serving as ground are connected together by bonding wire 1507.

In the fourth embodiment power amplifier 400 can adjust distortion in amplification by changing how in variable impedance circuit 30X having pads 1502-1505 connection portions 1405-1408 are connected. This allows power amplifier 400 to adjust compensation for distortion according for example to frequency, output, load and other specifications in a process for mounting a single, power amplifying integrated circuit.

In the fourth embodiment variable impedance circuit 30X is configured to vary resistance by a bonding wire connecting between pads 1502-1505 and die area 1506. However, variable impedance circuit 30X may be configured otherwise. For example, it can be configured to vary resistance for example on a printed circuit board by a jumper pin.

The conventional power amplifier 1200 shown in FIG. 24, for example, has variable impedance element 2201 arranged for the base of bipolar transistor 102 serving as an amplification element. Accordingly it is practically impossible to change connection after an integrated circuit is fabricated. In contrast, power amplification circuit 400 of the fourth embodiment is provided with variable impedance circuit 30X between the base of bipolar transistor 104 and a ground node. This allows connection to be changed after an integrated circuit is fabricated.

Thus the fourth embodiment provides power amplifier 400 including variable impedance circuit 30X allowing a resistor to be selected by means of a bonding wire or a jumper pin. While this prevents electrical adjustment of compensation for distortion after fabrication, as can be done for a MOSFET, it is advantageous in that there is no dc current consumed.

### Fifth Embodiment

FIG. 17 is a circuit diagram showing a circuit configuration of a power amplifier 500 in a fifth embodiment of the present invention.

Power amplifier 500 of the fifth embodiment shown in FIG. 17 differs from power amplifier 100 of the first embodiment in that variable impedance circuit 30 is replaced with a variable impedance circuit 30Y. The portion that overlaps the first embodiment will not be described repeatedly.

Variable impedance circuit 30Y differs from variable impedance circuit 30 in that MOSFET 112 is replaced with a connection portion 1602 via a line 1603. Variable impedance circuit 30Y is configured as will now be more specifically described hereinafter.

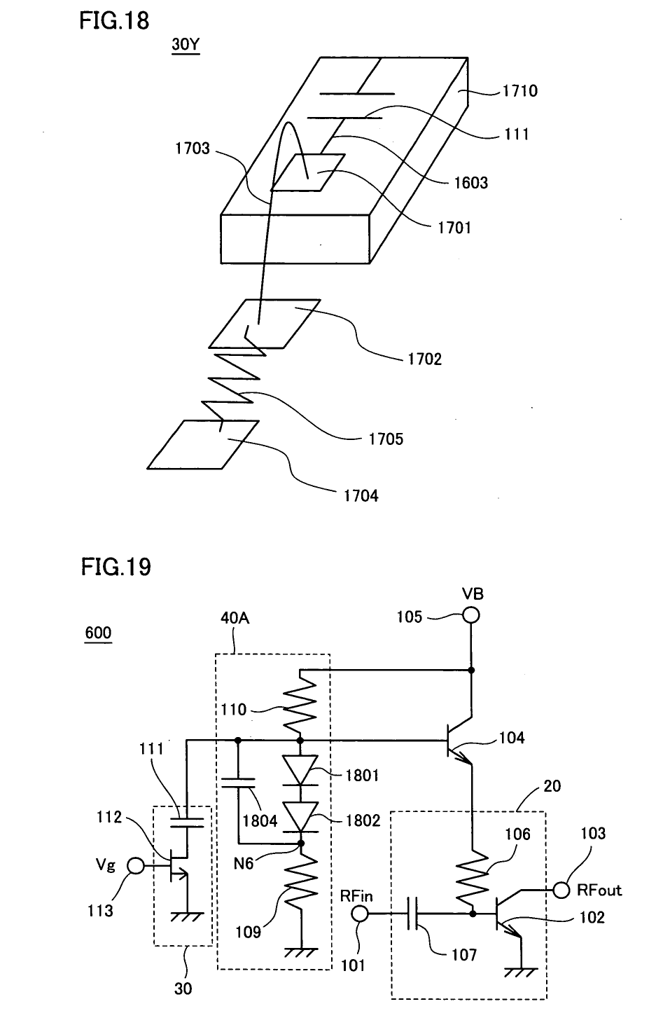

FIG. 18 specifically shows a configuration of variable impedance circuit 30Y in power amplifier 500.

With reference to FIG. 18, variable impedance circuit 30Y includes capacitor 111, line 1603, pads 1701 and 1702, a wire 1703, a ground node 1704, a resistor 1705, and a chip 1710. Chip 1710 has mounted thereon each component of power amplifier 500 including variable impedance circuit 30Y.

Line 1603 extends on chip 1710 and connects capacitor 111 and pad 1701 together. Pad 1701 is connected to pad 1702 external to chip 1710 by wire 1703. External to chip 1710, pad 1702 is connected via resistor 1705 to ground node 1704.

Variable impedance circuit 30Y changes resistor 1705 to a different resistance to vary in impedance. Power amplifier 500 can thus adjust distortion in amplification. Note that while variable impedance circuit 30Y has an impedance element implemented by resistor 1705, the present invention's impedance element is not limited to a resistor and it may be a capacitor or a different impedance element.

The fifth embodiment provides power amplifier 500 such that resistor 1705 for adjusting distortion in amplification of power amplifier 500 is arranged external to chip 1710. As such, even after chip 1710 has each component mounted thereon, power amplifier 500 can have resistor 1705 changed to adjust compensation for distortion in amplification.

Thus in the fifth embodiment if power amplifier 500 completed has variation in fabrication providing distortion in amplification different than designed, it is not necessary to introduce modification internal to chip 1710 to adjust distortion in amplification; simply introducing modification external to chip 1710 suffices to do so. Furthermore if power amplifier 500 in its research and experimental stage has distortion in amplification offset from its design, it can adjust distortion in amplification without modifying a circuit on chip 1710 in configuration.

### Sixth Embodiment

FIG. 19 is a circuit diagram showing a circuit configuration of a power amplifier 600 in a sixth embodiment of the present invention.

Power amplifier 600 of the sixth embodiment shown in FIG. 19 differs from power amplifier 100 of the first embodiment in that base voltage generation portion 40 is replaced with a base voltage generation portion 40A. The portion that overlaps the first embodiment will not be described repeatedly.

Base voltage generation portion 40A differs from base voltage generation portion 40 in that diodes 1801 and 1802 and a capacitor 1804 are additionally introduced. As has been described in the first embodiment in the first exemplary variation, diodes 1801 and 1802 are introduced for the purpose of improving a temperature characteristic in gain of power amplifier 600.

Diodes 1801 and 1802 are connected in series between the gate of bipolar transistor 104 and a node N6 (a first node). Capacitor 1804 is connected to diodes 1801 and 1802 in parallel. Resistor 109 is connected between node N6 and a ground node.

With reference to FIG. 2, when power amplifier 100 of the first embodiment operates in an environment low in temperature bipolar transistor 120 decreases in gain and the amplifier as a whole has an impaired characteristic. Accordingly, power amplifier 100 with base voltage generation portion 40 having resistor 109 replaced with diodes 1801 and 1802 will now be considered.

If in the above described case the surrounding temperature decreases, diodes 1801 and 1802 increase in impedance and bipolar transistor 104 has a base voltage pulled up. Consequently, bipolar transistor 102 at the base receives an increased dc current, which suppresses a decrease in gain of bipolar transistor 104.

Base voltage generation portion 40 that has resistor 109 replaced with diodes 1801 and 1802 allows diodes 1801 and 1802 to function as a temperature compensation circuit to prevent a power amplifier from having an impaired characteristic for low temperature. Power amplifier 100 with base voltage generation portion 40 having resistor 109 replaced with diodes 1801 and 1802, however, in some cases decreases in saturation output.

As a result of a study it has been found that the above phenomenon is not seen when, as seen in power amplifier 50 shown in FIG. 1 as background technology, variable impedance element 2201 is arranged between the base of bipolar transistor 102 and the emitter of bipolar transistor 104. Furthermore, it has been found that the above phenomenon is seen when, as seen in power amplifier 100 of the first embodiment shown in FIG. 2, variable impedance circuit 30 is arranged between the base of bipolar transistor 104 and a ground node and is also high in impedance.

With the above study considered, power amplifier 100 of the first embodiment with base voltage generation portion 40 having resistor 109 replaced with diodes 1801 and 1802, and with variable impedance circuit 30 high in impedance will further be studied and a result thereof will be described hereinafter.

If in the above case radio frequency signal RFin becomes large, the voltage applied to diodes 1801 and 1802 becomes high and a current starts to flow through diodes 1801 and 1802. As the current starts to flow through diodes 1801 and 1802, diodes 1801 and 1802 decrease in impedance and bipolar transistor 1804 has a decreased base voltage.

It has been found that as a result, bipolar transistor 104 between the base and the collector has a reduced current flowing therethrough and is thus not supplied with a sufficient current, and as a result a reduced saturation output is provided. To prevent this, the present inventors considered that preventing diodes 1801 and 1802 from having a current flowing therethrough when radio frequency signal RFin is input is important, and have found the circuit configuration of power amplifier 600 of the sixth embodiment shown in FIG. 19.

The sixth embodiment provides power amplifier 600 with base voltage generation portion 40A having diodes 1801 and 1802 with resistor 109 connected thereto in series. This circuit configuration allows voltage applied to diodes 1801 and 1802 to be attenuated at resistor 109. Diodes 1801 and 1802 can thus be prevented from having a current flowing therethrough.

Furthermore the sixth embodiment provides power amplifier 600 with base voltage generation portion 40A having diodes 1801 and 1802 with capacitor 1804 connected thereto in parallel. This circuit configuration can reduce a radio frequency voltage in amplitude across diodes 1801 and 1802 connected in series. Diodes 1801 and 1802 can thus be prevented from having a current flowing therethrough.

Connecting capacitor 1804 to diodes 1801 and 1802 in parallel is important. Connecting capacitor 1804 to resistor 109 and diodes 1801 and 1802 in parallel is not preferable, since if capacitor 1804 is connected to a ground node directly, capacitor 1804 would be smaller in impedance than variable impedance circuit 30. As a result, variable impedance circuit 30 receives a reduced radio frequency signal resulting in a reduced range of adjustment of distortion in amplification.

To prevent this the sixth embodiment provides power amplifier 600 having capacitor 1804 connected to diodes 1801 and 1802 in parallel and resistor 109 in series. This can set the impedance of resistor 109 and capacitor 1804 high.

### Seventh Embodiment

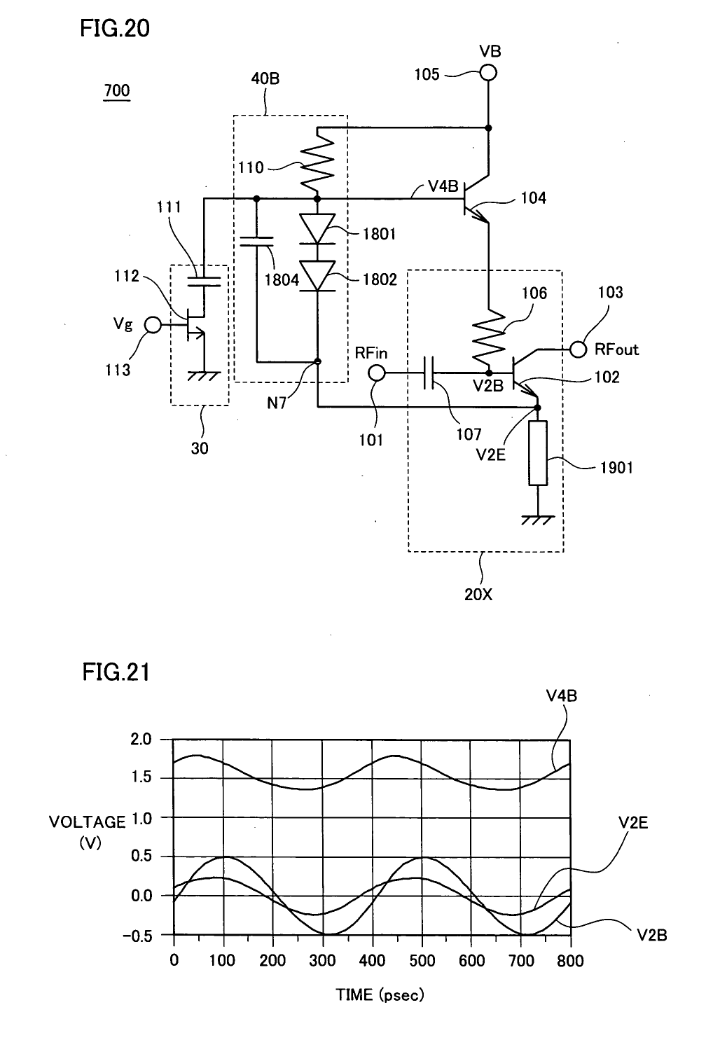

FIG. 20 is a circuit diagram showing a circuit configuration of a power amplifier 700 in a seventh embodiment of the present invention.

Power amplifier 700 of the seventh embodiment shown in FIG. 20 differs from power amplifier 100 of the first embodiment in that radio frequency signal input/output portion 20 and base voltage generation portion 40 are replaced with a radio frequency signal input/output portion 20X and a base voltage generation portion 40B, respectively. The portion that overlaps power amplifier 50 will not be described repeatedly.

Radio frequency signal input/output portion 20X differs from radio frequency signal input/output portion 20 in that an inductance circuit 1901 is additionally introduced. Base voltage generation portion 40B differs from base voltage generation portion 40 in that diodes 1801 and 1802 and capacitor 1804 are additionally introduced and resistor 109 is removed.

Inductance circuit 1901 is connected between the emitter of bipolar transistor 102 (or a node N7) and a ground node. Inductance circuit 1901 is implemented for example by a bonding wire used to connect the emitter to the ground node in mounting an integrated circuit.

Diodes 1801 and 1802 are connected between the gate of bipolar transistor 104 and node N7 in series. Capacitor 1804 is connected to diodes 1801 and 1802 in parallel. Note that capacitor 1804 shown in FIG. 20 fulfills the same role as capacitor 1804 of the sixth embodiment shown in FIG. 19.

FIG. 21 represents a relationship between time and voltage at each portion of power amplifier 700.

In FIG. 21 the horizontal axis represents time (psec) and the vertical axis represents voltage amplitude (V). With reference to FIGS. 20 and 21, voltages V2B, V4B and V2E represent waveforms in voltage of signals input to bipolar transistor 102 at the base, bipolar transistor 104 at the base, and bipolar transistor 102 at the emitter, respectively.

As shown in FIG. 21, connecting node N7 with diode 1802 connected thereto to bipolar transistor 102 at the emitter allows a voltage smaller in amplitude across diodes 1801 and 1802 connected in series than connecting diode 1802 directly or indirectly to a ground node. Diode 1801 and 1802 can thus be prevented from having a current flowing therethrough.

Thus the seventh embodiment provides power amplifier 700 that has node N7 connected to bipolar transistor 102 at the emitter and has inductance circuit 190 additionally introduced to reduce in amplitude a radio frequency voltage across diodes 1801 and 1802 series connected. Power amplifier 700 thus increases in saturation output.

### Eighth Embodiment

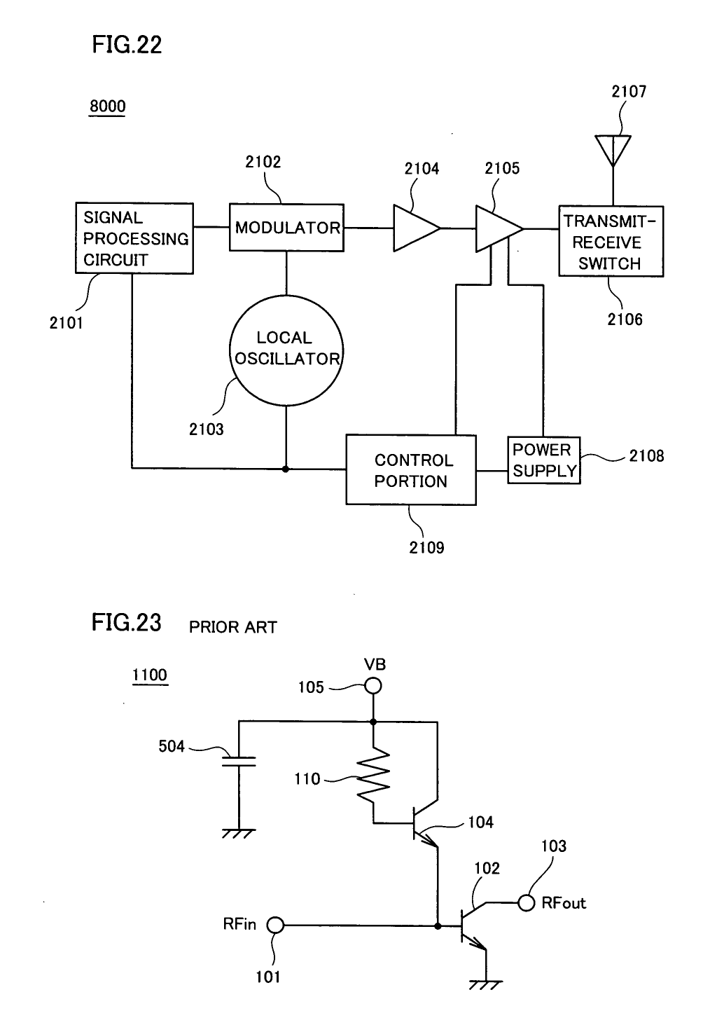

FIG. 22 is a block diagram schematically showing a configuration of a communication apparatus 8000 in an eighth embodiment of the present invention.

With reference to FIG. 22 the eighth embodiment provides communication apparatus 8000 including a signal processing circuit 2101, a modulator 2102, a local oscillator 2103, a driver amplifier 2104, a transmission power amplifier 2105, a transmit-receive selector switch 2106, an antenna 2107, a power supply 2108, and a control portion 2109.

Signal processing circuit 2101 processes a signal which is in turn modulated by modulator 2102 receiving a carrier signal from local oscillator 2103. The modulated signal is amplified by driver amplifier 2104 and further amplified by transmission power amplifier 2105. Transmission power amplifier 2105 outputs a signal to be transmitted, which is in turn transmitted via transmit-receive selector switch 2106 from antenna 2107. Power supply 2108 supplies transmission power amplifier 2105 with power.

Transmission power amplifier 2105 includes at least one of power amplifiers 100-700 of the first to seventh embodiments and power amplifier 50 serving as a background. Control portion 2109 adjusts distortion in amplification of transmission power amplifier 2105. Control portion 2109 can adjust distortion in amplification of transmission power amplifier 2105 depending on a state of signal processing circuit 2101, local oscillator 2103 and power supply 2108.

If communication apparatus 8000 of the eight embodiment causes transmission power amplifier 2105 to operate in a power saving mode, a high output mode, a communication system with a plurality of different frequency bands or a wide frequency band, and the like, it can adjust compensation for distortion in amplification according to each different mode of operation within itself Thus a communication apparatus can be implemented that includes a power amplifier capable of adjusting compensation for distortion in amplification according to different modes of operation.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A power amplifier receiving a signal at an input terminal, amplifying said signal, and outputting said signal thus amplified at an output terminal, comprising:
a radio frequency signal input/output portion including a first bipolar transistor having a base directly or indirectly connected to said input terminal, a collector connected to said output terminal, and an emitter grounded;
a voltage terminal supplying said radio frequency signal input/output portion with an operating voltage;
a second bipolar transistor having an emitter directly or indirectly connected to said base of said first bipolar transistor;
a base voltage generation portion generating a base voltage of said second bipolar transistor; and
a variable impedance circuit controlling impedance for a base of said second bipolar transistor.

2. The power amplifier according to claim 1, wherein said radio frequency signal input/output portion further includes;
a first resistor connected between said base of said first bipolar transistor and said emitter of said second bipolar transistor; and
a first capacitor connected between said input terminal and said base of said first bipolar transistor.

3. The power amplifier according to claim 1, wherein said base voltage generation portion includes:
a second resistor connected between said voltage terminal and said base of said second bipolar transistor; and
a third resistor connected between said base of said second bipolar transistor and a ground node.

4. The power amplifier according to claim 1, wherein said variable impedance circuit includes:
a second capacitor acting to be open for a direct-current component of said variable impedance circuit; and
a field effect transistor having a gate directly or indirectly connected to an impedance control terminal controlling an impedance for an alternate-current component of said variable impedance circuit by a gate voltage.

5. The power amplifier according to claim 2, wherein said radio frequency signal input/output portion includes more than one unit formed of said first bipolar transistor, said first resistor and said first capacitor.

6. The power amplifier according to claim 4, wherein said variable impedance circuit has:
said field effect transistor having a drain connected to said base of said second bipolar transistor, and a source connected to said second capacitor; and
said second capacitor connected between a source of said field effect transistor and a ground node.

7. The power amplifier according to claim 4, further comprising a voltage setting circuit connected to said gate of said field effect transistor, wherein said voltage setting circuit includes;
a fourth resistor connected between said impedance control terminal and said gate of said field effect transistor; and
a fifth resistor connected between said gate of said field effect transistor and a ground node.

8. The power amplifier according to claim 4, wherein said variable impedance circuit includes more than one unit formed of a sixth resistor further connected between said second capacitor and a drain of said field effect transistor and said field effect transistor.

9. The power amplifier according to claim 1, wherein:
said variable impedance circuit includes a second capacitor connected to said base of said second bipolar transistor, and more than one unit formed of a seventh resistor connected to said second capacitor and a connection portion controlling impedance;
said connection portion has a first pad connected to said seventh resistor, and a die area serving as ground; and
at least one of more than one said first pad and said die area are connected by a bonding wire.

10. The power amplifier according to claim 1, wherein:
said variable impedance circuit includes a second capacitor connected to said base of said bipolar transistor and a connection portion connected to said second capacitor via a line; and
said connection portion has a second pad connected to said second capacitor on a common chip, a third pad arranged external to said chip, and an eighth resistor connected between said third pad and a ground node; and
said second and third pads are connected together by a wire.

11. The power amplifier according to claim 1, wherein said voltage generation portion includes:
a second resistor connected between said voltage terminal and said base of said second bipolar transistor;
first and second diodes connected in series between said base of said second bipolar transistor and a first node;
a third capacitor connected to said first and second diodes in parallel; and
a ninth resistor connected between said first node and a ground node.

12. The power amplifier according to claim 1, wherein:
said radio frequency signal input/output portion further includes an inductance circuit connected between said emitter of said first bipolar transistor and a ground node; and
said base voltage generation portion includes a second resistor connected between said voltage terminal and said base of said second bipolar transistor,
first and second diodes connected in series between said base of said second bipolar transistor and said emitter of said first bipolar transistor,
and a third capacitor connected to said first and second diodes in parallel.

13. A power amplifier receiving an input signal at an input terminal, amplifying said signal, and outputting said signal thus amplified at an output terminal, comprising:
a radio frequency signal input/output portion including a first bipolar transistor having a base directly or indirectly connected to said input terminal, a collector connected to said output terminal, and an emitter grounded;
a voltage terminal supplying said radio frequency signal input/output portion with an operating voltage;
a second bipolar transistor having an emitter directly or indirectly connected to said base of said first bipolar transistor;
a base voltage generation portion including a second resistor connected between said voltage terminal and a base of said second bipolar transistor; and
a variable impedance circuit setting impedance for said base of said second bipolar transistor, wherein said radio frequency signal input/output portion further includes
a first resistor connected between said base of said first bipolar transistor and an emitter of said second bipolar transistor,
a first capacitor connected between said input terminal and said base of said first bipolar transistor, and
a variable impedance element connected between said input terminal and said emitter of said second bipolar transistor.

14. A communication apparatus comprising a power amplifier receiving a signal at an input terminal, amplifying said signal, and outputting said signal thus amplified at an output terminal, said power amplifier including:
a radio frequency signal input/output portion including a first bipolar transistor having a base directly or indirectly connected to said input terminal, a collector connected to said output terminal, and an emitter grounded;
a voltage terminal supplying said radio frequency signal input/output portion with an operating voltage;
a second bipolar transistor having an emitter directly or indirectly connected to said base of said first bipolar transistor;
a base voltage generation portion generating a base voltage of said second bipolar transistor; and
a variable impedance circuit controlling impedance for a base of said second bipolar transistor.

15. The communication apparatus according to claim 14, comprising:
a signal processing circuit processing an input signal;
a local oscillator oscillating a carrier signal;
a modulator receiving said carrier signal to modulate said signal thus processed; and
a transmission power amplifier amplifying said signal thus modulated, wherein said transmission power amplifier includes said power amplifier.

16. The communication apparatus according to claim 15, further comprising:
a power supply supplying said transmission power amplifier with power; and
a control portion adjusting distortion in amplification of said transmission power amplifier depending on a state of said signal processing circuit, said local oscillator and said power supply.
